(19) United States
(12) Patent Application Publication
(10) Pub. No.: US 2005/0164099 A1
(43) Pub. Date: Jul. 28, 2005

(54) Method to overcome minimum photomask dimension rules

(76) Inventor: Tito Gelsomini, Plano, TX (US)

Correspondence Address: TEXAS INSTRUMENTS INCORPORATED, P O BOX 655474, M/S 3999, DALLAS, TX, 75265, US

(21) Appl. No.: 10/767,357

(22) Filed: Jan. 28, 2004

(51) Int. Cl. G03F 9/00; H01L 21/335

(52) U.S. Cl. 430/5; 430/4; 430/22; 430/311

(57) ABSTRACT

A method for fabricating a semiconductor device comprising at least one component having photolithographic proximity-limited geometries (702). The method comprises the steps of dividing the component into a plurality of sub-geometries (703), wherein each of these sub-geometries contains only structural elements spaced far enough to be compatible with photomask rules. A separate photomask (704) is then made for each of the sub-geometries. Each of these photomasks is sequentially used in a plurality of photoresist printing steps (705) so that the semiconductor device component is created step by step.

### FIELD OF THE INVENTION

The present invention is related in general to the field of semiconductor devices and processes, and more specifically to the structure and fabrication processes of photomasks and the corresponding integrated circuit devices.

### DESCRIPTION OF THE RELATED ART

Among the dominating trends in the semiconductor device technology, especially in integrated circuits, are the trends toward higher functional integration and further geometrical miniaturization. As an example, the feature sizes of many device components have shrunk below the wavelength of visible light already several years ago. In spite of this fact, the geometries of the components continue to be defined and fabricated with the help of photoresists and photomasks.

Driven by the need to achieve higher device speed, diminish component interconnection and simplify device complexity, circuit designers feel frequently compelled to squeeze component features geometrically so close together that the component proximity runs into resolution and interference problems during the multiple photolithographic fabrication steps. In an effort to control the shapes of geometries otherwise distorted by their optical proximity interference, optical proximity corrections (OPC) have been generated and consequently rules have been established, which circuit designers are supposed to respect and follow. These rules associated with OPC of geometries specify the minimum distances, which the component features are required to maintain to guarantee successful fabrication of the photomasks; these rules thus control the design of photomasks.

Demands of customers and the competition in the marketplace, however, are often stronger forces than the design-limiting rules. Consequently, circuit designers are often under pressure to marginalize or even violate the OPC rules, sometimes at the risk of process yield loss, or to jeopardize the possibility of manufacturing the photomasks. With continued shrinkage of the component feature sizes at each advanced technology node, it is becoming progressively more difficult, to transfer in full all the benefits of the OPC in the photomask, especially at the high density and thus proximity of device contacts or polysilicon geometries. More and more often, the circuit design calls for photomasks, for which the manufacturing rules will not allow the full application of the OPC. Compromises may affect the manufacturability of the photomasks, or the reliability and the yield of the semiconductor device.

A need has therefore arisen for a comprehensive method to overcome the minimum photomask dimension rules. The method should be low cost and flexible enough to be applied for different semiconductor product families and a wide spectrum of design variations, especially concerning device contact pads. The method should also achieve improvements toward the goals of improved process yield and device reliability. Preferably, these innovations should be accomplished using the installed equipment base so that no investment in new manufacturing machines is needed.

### SUMMARY OF THE INVENTION

One embodiment of the invention is a method for fabricating a semiconductor device comprising at least one component having photolithographic proximity-limited geometries. The method comprises the steps of dividing the component into a plurality of sub-geometries, wherein each of these sub-geometries contains only structural elements spaced far enough to be compatible with photomask rules. A separate photomask is then made for each of the sub-geometries. Each of these photomasks is sequentially used in a plurality of photoresist printing steps so that the semiconductor device component is created step by step.

Another embodiment of the invention is a set of photomasks to be used in the fabrication of semiconductor devices comprising at least one component having photolithographic proximity-limited geometries. The set comprises a plurality of photomasks, wherein each of these photomasks is intended for fabricating one sub-geometry of the component. The sub-geometry is selected so that it contains only structural elements spaced far enough to be compatible with photomask rules. The sequential use of each of these photomasks in a plurality of photoresist printing steps creates the device component step by step.

Embodiments of the present invention are related to high density integrated circuits (ICs), especially those having high numbers of inputs/outputs, or contact pads. These ICs can be found in many semiconductor device families such as standard linear and logic products, digital signal processors, microprocessors, wireless devices, digital and analog devices, SRAM memory arrays, and both large and small area chip categories.

It is a technical advantage of one or more embodiments of the invention that the embodiments can reach the goals of the invention with a low-cost manufacturing method without the cost of equipment changes and new capital investment, by using the installed fabrication equipment base.

In another technical advantage of the embodiments of the invention, the requirements for photomasks can be relaxed by dispersing a crowded plurality of components into less crowded geometries, followed by multiple printing. The limitations of the optical proximity corrections with respect to mask manufacturing can thus be alleviated.

Another advantage which may flow from one or more embodiments of the invention is the ability to produce components of integrated circuits so that the minimum feature sizes of technology nodes may shrink more rapidly and the minimum photomask dimension rules can leapfrog to smaller dimensions. These features, in turn, support the trend towards device miniaturization and higher integration.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 is a schematic top view of a portion of a semiconductor device comprising a component having photolithographic proximity-limited geometries.

FIG. 2 is a schematic top view of a portion of a semiconductor device comprising a component having photolithographic proximity-limited geometries, embedded in an X-Y coordinate system.

FIG. 3 is a schematic top view of a sub-geometry of the component in FIG. 2, embedded in the same X-Y coordinate system as in FIG. 2.

FIG. 4 is a schematic top view of another sub-geometry of the component in FIG. 2, embedded in the same X-Y coordinate system as in FIG. 2.

FIG. 5 is a schematic top view of another sub-geometry of the component in FIG. 2, embedded in the same X-Y coordinate system as in FIG. 2.

FIG. 6 is a schematic top view of another sub-geometry of the component in FIG. 2, embedded in the same X-Y coordinate system as in FIG. 2.

FIG. 7 depicts schematically an embodiment of the invention, the method of fabricating a semiconductor device comprising at least one component having photolithographic proximity-limited geometries.

### DETAILED DESCRIPTION OF THE PREFERRED EMBODIMENTS

The advances offered by the present invention can be best appreciated by comparing them with the shortcomings of the present technology. As a drastic example taken from the layout of an arbitrary integrated circuit (IC), the schematic top view of FIG. 1 depicts a circuit component, generally designated 100, having four original features 101, 102, 103, and 104. These features in the surface 190 of the semiconductor material may, for instance, be intended to become contact pads, windows for ion implantation, or polysilicon geometries.

The features have various geometrical distances between their adjacent sides or at their respective closest proximity. The distance between the adjacent sides of features 101 and 102 is designated 111; the distance between features 102 and 103 is designated 112; the distance between features 103 and 104 is designated 113; and the distance between features 104 and 101 is designated 114. Among the plurality of distances depicted in the example of FIG. 1, the smallest distance is separation 114 between features 104 and 101. For instance, in the 90 nm technology node of the semiconductor industry, distance 114 may be 90 nm, which by itself would not violate the minimum spacing between geometries.

In contrast, the manufacture of the photomasks needed to produce component 100 faces a serious difficulty. The reason is that in order to create the features of FIG. 1, photomasks are needed, which have to be manufactured in accordance with the shapes generated by means of optical proximity corrections (OPC). According to these rules, each original feature of the component in FIG. 1 is transformed into a photomask feature, which in principle has a tolerance range around the original feature contours. The size of the tolerance range is determined by the optical proximity corrections (OPC). In the example of FIG. 1, the area of frame 101a has to be reserved in the photomask in order to reliably create original feature 101. Similarly, frame 102a has to be reserved for creating original feature 102, frame 103a for original feature 103, and frame 104a for original feature 104.

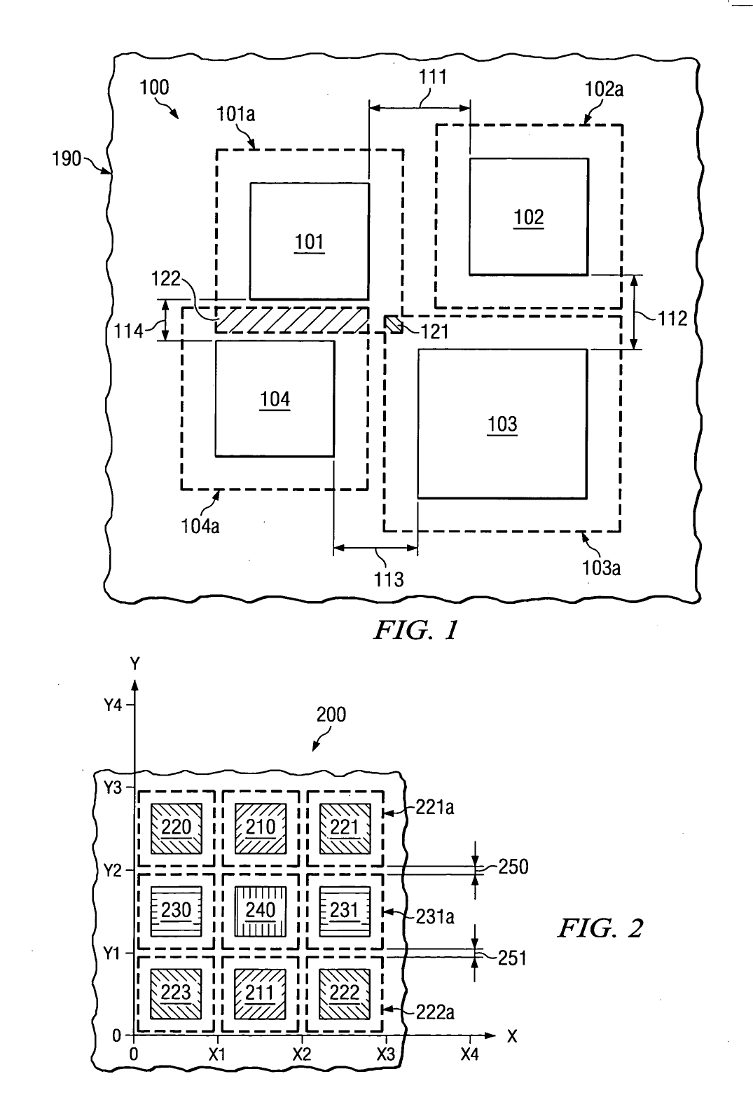

As can be seen in FIG. 1, there is an overlap of frame 101a with frame 103a throughout corner area 121, and an overlap of frame 101 with frame 104a throughout side area 122. These overlaps violate the full application of the photomask manufacturing rules. How the present invention solves this dilemma is discussed in conjunction with the solution to the more common dilemma shown in FIG. 2.

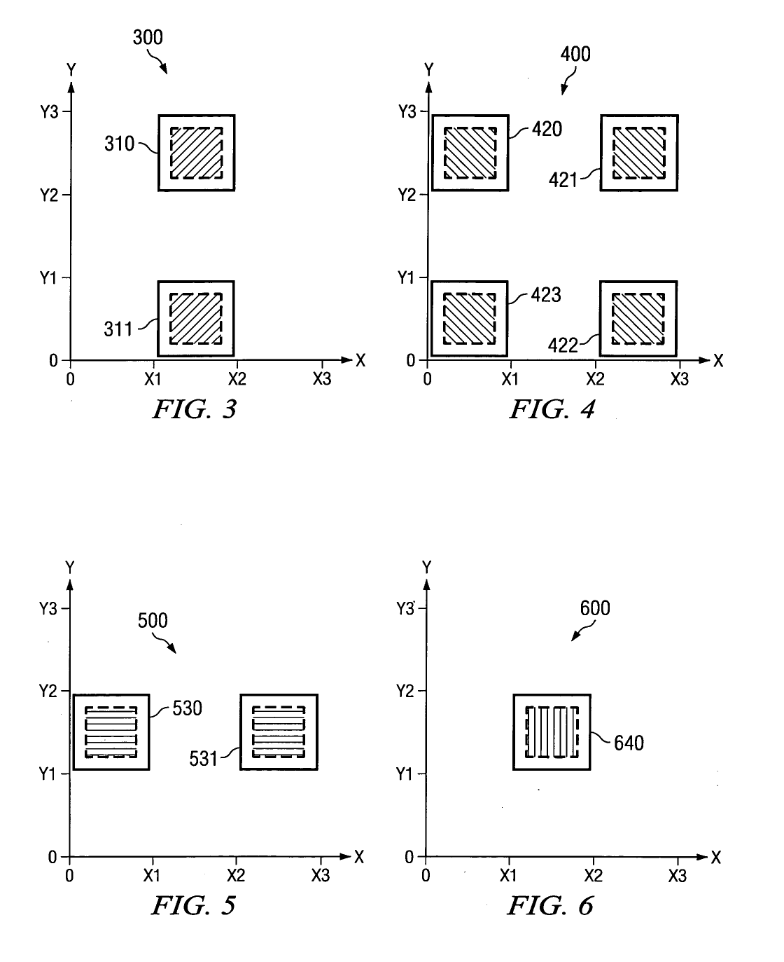

One embodiment of the present invention is a method, illustrated in FIGS. 2 to 6, for fabricating a semiconductor device, which has at least one component with photolithographic proximity-limited geometries. The schematic top view of FIG. 2 illustrates a portion of a semiconductor device comprising a component, generally designate 200, which has two-dimensional, photographic proximity-limited structures, referred to here as “geometries”. In the example of FIG. 2, the component consists of a plurality of original geometries outlined by solid lines; the original geometries of this example have rectangular shape, and may, for instance, serve in the IC as contact pads, silicided device areas, or windows for ion implantation. The plurality of geometries is organized in sub-groups, which are indicated in FIG. 2 by a variety of shadings (the rationale for the organization is explained in FIGS. 3 to 6). One type of shading includes the original geometries 210 and 211. Another type of shading includes the original geometries 220, 221, 222, and 223. Another type of shading includes the original geometries 230 and 231. Yet another type of shading includes the original geometry 240.

Each original geometry is surrounded by another geometry, indicated by dashed lines in FIG. 2, which substitutes in the photomask for the original geometry in order to comply with the rules of the optical proximity corrections (OPC). In the following description, the reserved areas are referred to as “OPC areas”. The extent of the reserved OPC areas is indicated in FIG. 2 by dashed lines. As can be seen, the outlines define rectangular areas in FIG. 2, consisting of the original geometry plus the surrounding frame. As examples, geometry 221 is surrounded by frame area 221a, geometry 231 is surrounded by frame area 231a, and geometry 222 is surrounded by frame area 222a.

Furthermore, an X-Y coordinate system is shown, with the units on each axis indicated by X1, X2, X3, etc., and Y1, Y2, Y3, etc. The X-Y coordinate system attributes unique coordinates to each point of the geometries and OPC areas, in particular to the defining corner points of the rectangles.

In the example of FIG. 2, the smallest feature sizes are the distances between two adjacent OPC frames, such as the separation 250 between OPC frames 221a and 231a, and separation 251 between OPC frames 231a and 222a. If the feature size of separations 250 and 251 are smaller than the OPC dictated by the photomask manufacturers, the photomasks to produce component 203 cannot be made with the full benefits of the OPC for that technology node, since these OPC frames need to be modified to comply with the photomask rules.

In the embodiment of the invention illustrated in FIGS. 3 to 6, the component 200 is divided into a plurality of sub-groups, or sub-geometries, wherein each sub-group, or sub-geometry contains only structural elements spaced far enough to be compatible with the optical proximity correction rules of the technology node. The structures appearing in the photomask are outlined in solid lines; each of these structures includes, in dashed lines, the original geometry as it will be produced in the IC; these original geometries are outlined in dashed lines. The sub-geometries are defined within an X-Y coordinate system, which is the same identical system for all sub-groups in order to guarantee a perfect match of all sub-geometries for creating the IC component.

FIG. 3 shows one sub-group of the component 200 in FIG. 2, the sub-geometry 300 consisting of structures 310 and 311. These structures are embedded in the X-Y coordinate system so that structures 310 and 311 have the same coordinates as the OPC frames of structure 210 and 211 in FIG. 2. FIG. 3 clearly illustrates that structures 310 and 311 have been selected and are spaced far enough to be compatible with the photomask rules of the technology node. Based on the configuration of FIG. 3, a separate photomask for the illustrated sub-geometry can be manufactured.

FIG. 4 shows another sub-group of the component 200 of FIG. 2, the sub-geometry 400 consisting of structures 420, 421, 422, and 423 as they are embedded in the same X-Y coordinate system as in FIG. 2. The structures 420 etc. are outlined in solid lines, and the original geometries as they will be produced in the IC are outlined in dashed lines. As FIG. 4 shows, structures 420, 421, 422, and 423 have been selected and are spaced far enough to be compatible with the photomask rules of the technology node. A separate photomask for the sub-geometry 400 can thus be manufactured.

FIG. 5 shows another sub-group of the component 200 of FIG. 2, the sub-geometry 500 consisting of structures 530 and 531 as they are embedded in the same X-Y coordinate system as in FIG. 2. As FIG. 5 demonstrates, structures 530 and 531 have been selected and are spaced far enough to be compatible with the photomask rules. Consequently, a separate photomask for the sub-geometry can be manufactured.

FIG. 6 depicts another sub-group of the component 200 in FIG. 2, the sub-geometry 600 consisting of structure 640 as it is embedded in the same X-Y coordinate system as in FIG. 2. Obviously, there is no problem to produce a separate photomask for the sub-structure in FIG. 6, which obeys all photomask rules.

After producing the separate photomasks for the sub-geometries described in FIGS. 2 to 6, they are sequentially used in a plurality of photoresist printing steps to create the semiconductor device component of FIG. 2 step by step. The consecutive masks are oriented in the alignment and printing machine under the guidance of the common X-Y coordinate system. There is, therefore, no chance for mask-related misalignment (excluding individual machine-related mistakes), and the component of FIG. 2 can be flawlessly fabricated even when the separations 250, 251 etc, in FIG. 2 are smaller than the allowed proximity limits as dictated by the photomask rules.

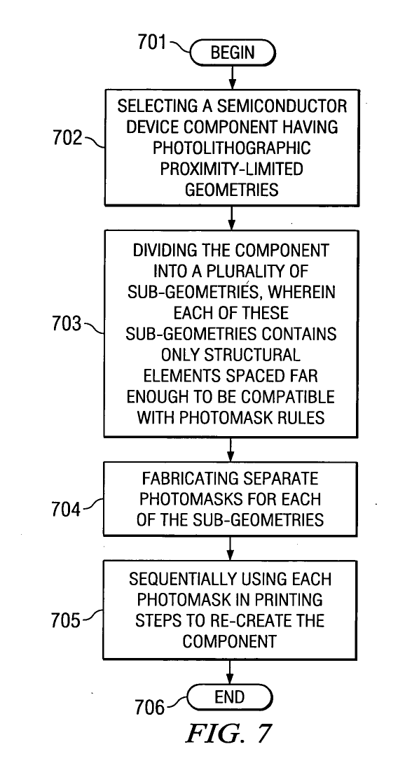

The method for fabricating a semiconductor device comprising at least one component having photolithographic proximity-limited geometries can be summarized by the steps shown in FIG. 7. At the begin 701 of the method, the component with photolithographic proximity-limited geometries is selected (702). The method continues with the step 703 of dividing the component into a plurality of sub-geometries, wherein each of these sub-geometries contains only structural elements spaced far enough to be compatible with photomask rules. A step 704, a separate photomask is made for each of the sub-geometries. Each of these photomasks is sequentially used in a plurality of photoresist printing steps 705 so that the semiconductor device component is created step by step.

For any particular technology node, it is a technical advantage of the invention to bypass the geometry limitations imposed by the photomask manufacturing rules, until the process limitations of that particular technology node are reached. As an example, if for a particular technology node the minimum allowed distances 250 and 251 in FIG. 2 are 90 nm, the invention provides a bypass of this limitation to the point, where the process limitations at that particular technology node are. These process limits may be around 70 nm. Consequently, in this example the invention permits a reduction of the minimum feature size of approximately 20%.

Another embodiment of the present invention is a set of photomasks, which are used in the fabrication of semiconductor devices, wherein the device has at least one component with photolithographic proximity-limited geometries. This set comprises a plurality of photomasks intended for the fabrication of one sub-geometry of the component. Each of these sub-geometries contains only structural elements spaced far enough to be compatible with photomask rules. The sequential use of each of these photomasks in a plurality of photomask printing steps creates the device component step by step. The sub-geometries of each photomask are controlled by the same X-Y coordinate system, which is used in the photomask alignment and printing machine to reproduce and fabricate the original IC component with its proximity-limited geometries.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description.

As an example, the method of dispersing geometries too close for photomask manufacturing rules into a set of separate photomasks, each one having a geometry in full compliance with photomask manufacturing rules, and a sequence of consecutive photomask printing steps to re-create the original geometry, may be applied to create closely spaced contacts, ion implanted doping profiles, metallized areas and other features of integrated circuits.

It is therefore intended that the appended claims encompass any such modifications and embodiments.

1. A method for fabricating a semiconductor device comprising at least one component having photolithographic proximity-limited geometries, comprising the steps of:
dividing said component into a plurality of sub-geometries, wherein each of said sub-geometries contains only structural elements spaced far enough to be compatible with photomask rules;
producing a separate photomask for each of said sub-geometries; and
sequentially using each of said photomasks in a plurality of photoresist printing steps so that said semiconductor device component is created step by step.

2. A set of photomasks to be used in the fabrication of semiconductor devices comprising at least one component having photolithographic proximity-limited geometries, said set comprising:
a plurality of photomasks, each of said photomasks intended for fabricating one sub-geometry of said component; wherein
each of said sub-geometries contains only structural elements spaced far enough to be compatible with photomask rules; and
the sequential use of each of said photomasks in a plurality of photoresist printing steps creates said device component step by step.
